(19) United States
(12) Patent Application Publication
(10) Pub. No.: US 2011/0304341 A1
(43) Pub. Date: Dec. 15, 2011

(54) METHOD OF TESTING INTEGRATED CIRCUITS

(75) Inventor: Ming-Shyi Wu, Chupei (TW)

(73) Assignee: MACRONIX INTERNATIONAL CO., LTD., Hsinchu (TW)

(21) Appl. No.: 12/797,786

(22) Filed: Jun. 10, 2010

(51) Int. Cl. G01R 31/02

(52) U.S. Cl. 324/537

(57) ABSTRACT

A method of testing integrated circuits includes providing an integrated circuit test system that has a voltage supply and a plurality of control channels. A first switching element is connected between the voltage supply and a first integrated circuit, and a second switching element is connected between the voltage supply and the second integrated circuit. The switching elements can include, for example, electromagnetic relays. The relays are controlled by respective test system control channels to selectively provide electrical power to each of the integrated circuits.

### BACKGROUND

1. Technical Field

The present application relates to the testing of integrated circuits, including the testing of memory devices.

2. Related Art

The manufacturing of integrated circuits involves processing a wafer through a series of fabrication steps in order to fabricate multiple integrated circuits on the wafer. Once the wafer has been processed, the wafer is cut into individual integrated circuits, which can then undergo further processing involving various bonding and packaging steps. However, it is desirable to test the operation of the integrated circuits before use. In some cases, the integrated circuits can be tested before the wafer is cut. Additionally or alternatively, the integrated circuits can be tested after the bonding and packaging steps. Such tests are typically made in order to verify various electrical properties of the integrated circuits. The information from these tests can be fed into a computer, which compares the test results with information stored in its memory, and render a decision regarding the acceptability of the integrated circuit.

Automatic test equipment (ATE) is commercially available for performing automated testing of integrated circuits. For example, one well-known example of ATE is a wafer tester for integrated circuits that is sold under the designation “Kalos 1” and manufactured by Credence Systems Corporation. The Kalos 1 is designed to test Flash memory. The Kalos 1 includes a probe card that includes sixteen test sites, one for each device under test (DUT).

Since integrated circuits are tested individually, testing is a time consuming processes. Thus, considerable effort has been put into improving the efficiency of the testing process. However, despite such efforts, there remains a need for further improvement in the efficiency of the testing of integrated circuits.

### SUMMARY

Testing devices and methods associated with testing devices are described herein. According to one aspect of the present disclosure, methods of testing a plurality of integrated circuits are disclosed that include the use of an integrated circuit test system that includes a voltage supply and a plurality of communication channels. The method can include utilizing select communication channels as control channels. A first switching element is connected between the voltage supply and a first integrated circuit to be tested, and a second switching element is connected between the voltage supply and a second integrated circuit to be tested. Still further integrated circuits to be tested can be connected in this manner up to a predetermined number of integrated circuits using respective switching elements. The method then includes controlling the switching elements using respective communication channels that have been designated as control channels.

The disclosed method can include the use of a known integrated circuit test system, for example a Kalos 1 test system.

In some embodiments, the switching elements can include relays or other electronically controllable switching devices. The relays or other such switching devices can include respective control terminals for receiving respective control signals via respective control channels. Also, in some embodiments, the method can include the use of a current clamp between the voltage supply and one or more of the integrated circuits being tested.

According to one aspect of the present disclosure, an apparatus for testing a plurality of integrated circuits comprises an integrated circuit test system that includes a voltage supply and a plurality of communication channels. The plurality of communication channels include communication channels that are designated as respective control channels. The apparatus also includes an expansion system. The expansion system comprises a plurality of switching elements connected between the voltage supply of the test system and respective integrated circuits to be tested. The communication channels designated as control channels are configured to control respective switching element.

In some embodiments, the integrated circuit test system can include a Kalos 1 test system.

In some embodiments, the switching elements can include relays or other electronically controllable switching devices. The relays or other such switching devices can include respective control terminals for receiving respective control signals via respective control channels. Also, in some embodiments, a current clamp can be connected between the voltage supply and one or more of the integrated circuits being tested.

### BRIEF DESCRIPTION OF THE DRAWINGS

Features, aspects, and embodiments of the inventions are described in conjunction with the attached drawings, in which:

FIG. 1 shows a partial block diagram of an integrated circuit (IC) test system;

FIG. 2 shows a block diagram of an embodiment of an expansion system according to the present disclosure; and

FIG. 3 shows another block diagram of the expansion system shown in FIG. 2.

### DETAILED DESCRIPTION

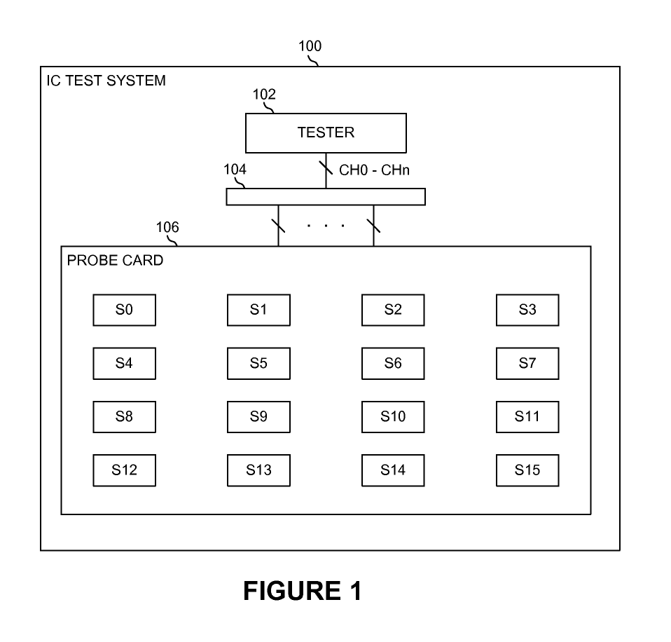

FIG. 1 shows a partial block diagram of an integrated circuit (IC) test system 100. The IC test system 100 can include commercially-available test systems, for example the Kalos 1. IC test system 100 allows for parallel testing of a limited number of DUT's. The IC test system 100 can include a tester 102, a multiplexer, 104, and a probe card 106. In some embodiments, the tester 102 and/or multiplexer 104 can actually be carried by the probe card 106 and/or otherwise integrated with the probe card 106. The probe card 106 can include a plurality of test sites S0-S15 that are each capable of independently testing a respective IC (DUT). Specifically, in the embodiment shown in FIG. 1, there are a total of sixteen test sites S0-S15. The test sites S0-S15 can electrically interface with respective DUT's, e.g., via respective contact patterns, so as to allow for parallel testing of multiple DUT's.

The probe card 106 is configured to interface with an IC and perform a number of tests according to signals from the tester 102 in order to verify various electrical properties of the IC. The IC test system 100 can include programmable attributes, which allow the end-user some degree of flexibility for adapting the IC test system 100 for various tests. For example, the communications between the tester 102 and test sites S0-S15 are carried by a plurality of communication channels CH0-CHn, where n represents a value according to the total number of channels, which can vary among different embodiments. The multiplexer 104 distributes the channels to the test sites S0-S15. It will be appreciated that the IC test system 100 can further include additional elements known in the art to be associated with IC test systems.

The present disclosure provides for an expansion system that allows for increasing the testing capacity of existing test systems such as the IC test system 100. The expansion system disclosed herein is particularly well-suited for expanding the throughput of a Kalos 1 tester; however, alternative embodiments can be adapted for use with other IC test systems.

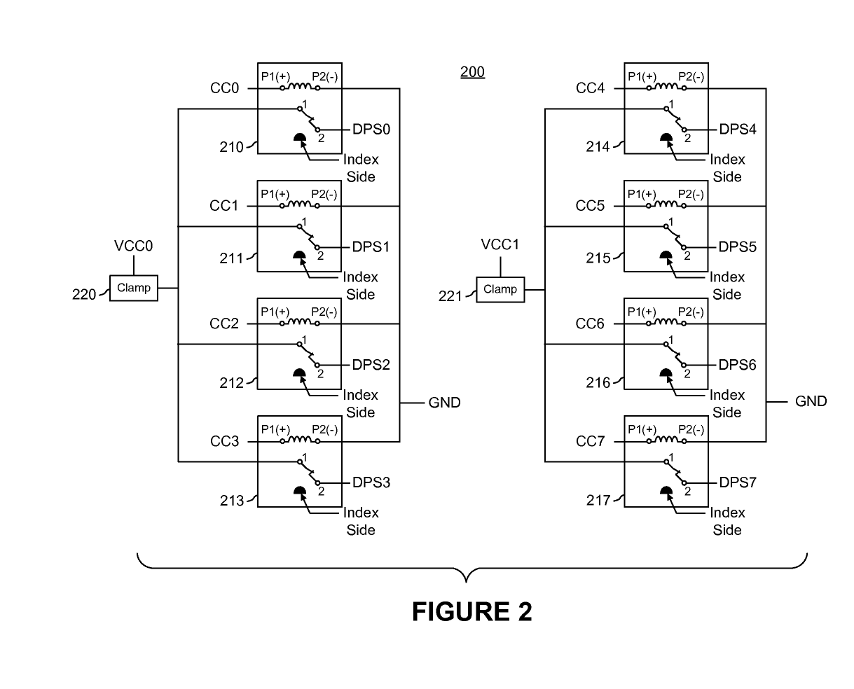

FIG. 2 shows a block diagram of an embodiment of an expansion system 200 according to the present disclosure. The expansion system 200 includes a plurality of electrically operated switches, for example relays 210-217. A first group of relays 210 through 213 are electrically connected to a first test system power supply VCC0. A second group of relays 214 through 217 are electrically connected to a second test system power supply VCC1.

The expansion system 200 uses relays 210-217 to separate two test system power supplies VCC0 and VCC1 into eight distributed power supply points DPS0-DPS7 through the use of relays 210-217. The relays 210-217 are controlled by the IC test system 100. More specifically, each of the relays 210-217 is controlled by a respective one of control channels CC0-CC7. The control channels CC0-CC7 can be any desired channels of the communication channels CH0-CHn of the IC test system 100.

The relays 210-217 can be electromagnetic relays that include an electromagnet to operate a switching mechanism. Each electromagnet includes control terminal P1 and control ground terminal P2. The control terminal P1 of the first relay 210 is connected to the first control channel CC0. The control terminal P1 of the second relay 211 is connected to the second control channel CC1. The control terminal P1 of the third relay 212 is connected to the third control channel CC2. The control terminal P1 of the fourth relay 213 is connected to the fourth control channel CC3. The control terminal P1 of the fifth relay 214 is connected to the fifth control channel CC4. The control terminal P1 of the sixth relay 215 is connected to the sixth control channel CC5. The control terminal P1 of the seventh relay 216 is connected to the seventh control channel CC6. The control terminal P1 of the eighth relay 217 is connected to the eighth control channel CC7. Thus, each of the relays 210-217 is connected to receive a control signal from a respective one of the control channels CC0-CC7. The control ground terminal P2 of each of the relays 210-217 is connected to ground.

Each of the relays 210-217 includes an input terminal 1 and an output terminal 2. Each of the relays 210-217 includes a respective switching element that switches an electrical connection such that an electrical connection between the input terminal 1 and the output terminal 2 is either open or closed. The input terminals 1 of each of the first through fourth relays 210-213 is connected to receive electrical power from the first power supply VCC0. The input terminals 1 of each of the fifth through eighth relays 214-217 is connected to receive electrical power from the second power supply VCC1.

The switching element of the first relay 210 is controlled by the first control channel CC0 to either be in an ON state, where the input and output terminals 1 and 2 are connected, or to be in an OFF state, where the input and output terminals 1 and 2 are disconnected. For example, the first relay 210 can be ON when the control signal from the first control channel CC0 is at a high level, for example 3.3 volts or 5 volts, and the first relay 210 can be OFF when the control signal from the first control channel CC0 is at a low level, for example 0 volts. When the first relay 210 is in the ON state, the electrical power from the first power supply VCC0 is provided to terminal 2, where the electrical power is provided to the first distributed power supply point DPS0. When the first relay 210 is in the OFF state, the electrical power from the first power supply VCC0 is disconnected from terminal 2.

The respective switching elements of the second through eighth relays 211-217 are similarly controlled by respective control channels CC1-CC7. The second control channel CC1 can control whether electrical power from the first power supply VCC0 is provided to the second distributed power supply point DPS1. The third control channel CC2 can control whether electrical power from the first power supply VCC0 is provided to the third distributed power supply point DPS2. The fourth control channel CC3 can control whether electrical power from the first power supply VCC0 is provided to the fourth distributed power supply point DPS3. The fifth control channel CC4 can control whether electrical power from the second power supply VCC1 is provided to the fifth distributed power supply point DPS4. The sixth control channel CC5 can control whether electrical power from the second power supply VCC1 is provided to the sixth distributed power supply point DPS5. The seventh control channel CC6 can control whether electrical power from the second power supply VCC1 is provided to the seventh distributed power supply point DPS6. The eighth control channel CC7 can control whether electrical power from the second power supply VCC1 is provided to the eighth distributed power supply point DPS7.

In some embodiments, additional circuitry can be included for controlling characteristics of the electrical power provided from the power supplies VCC0 and VCC1 to the distributed power supply points DPS0-DPS7. For example, a first current clamp 220 can be provided between the first power supply VCC0 and the first group of relays 210-213; and a second current clamp 221 can be provided between the second power supply VCC1 and the second group of relays 214-217. In some embodiments, the first and second current claims 220 and 221 can limit the electrical current to be no greater than 500 milliamps. The first and second current clamps 220 and 221 can include circuitry for preventing current spikes or otherwise limiting the magnitude of the electrical current to the distributed power supply points DPS0-DPS7. Alternatively, current clamps can be provided between each of the relays 210-217 and respective distributed power supply points DPS0-DPS7, respectively.

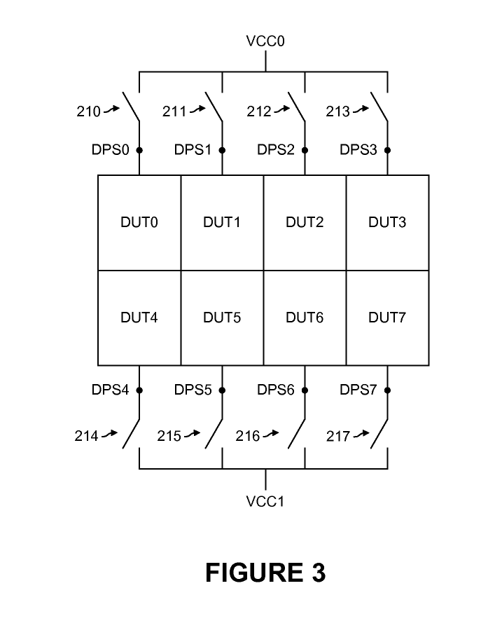

FIG. 3 shows another block diagram of the expansion system 200 according to the present disclosure. As shown in FIG. 3, each of the relays 210-217 can be connected so as to selectively provide electrical power to a respective DUT. The first relay 210 can selectively provide electrical power from the first power supply VCC0 to the first DUT0. The second relay 211 can selectively provide electrical power from the first power supply VCC0 to the second DUT1. The third relay 212 can selectively provide electrical power from the first power supply VCC0 to the third DUT2. The fourth relay 213 can selectively provide electrical power from the first power supply VCC0 to the fourth DUT3. The fifth relay 214 can selectively provide electrical power from the second power supply VCC1 to the fifth DUT4. The sixth relay 215 can selectively provide electrical power from the second power supply VCC2 to the sixth DUT5. The seventh relay 216 can selectively provide electrical power from the second power supply VCC1 to the seventh DUT6. The eighth relay 217 can selectively provide electrical power from the second power supply VCC1 to the eighth DUT7. Each DUT can include a respective IC. For example, each DUT can include a respective Flash memory device.

Thus, the expansion system 200 allows each of the test sites S0-S15 to test eight IC's. The expansion system 200 can thereby expand the throughput of the IC test system 100 having sixteen test sites S0-S15 to test 128 DUT's.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A method of testing a plurality of integrated circuits, the plurality of integrated circuits including a first integrated circuit and a second integrated circuit, the method comprising:
selecting a first communication channel to be a first control channel and a second communication channel to be a second control channel, wherein the first and second communication channels are communication channels of an integrated circuit test system that includes a voltage supply;
connecting a first switching element between the voltage supply and the first integrated circuit;
connecting a second switching element between the voltage supply and the second integrated circuit; and
controlling the first and second switching elements using the first and second control channels, respectively.

2. The method of claim 1, wherein the integrated circuit test system includes a Kalos 1 test system.

3. The method of claim 1, wherein the first switching element includes a first relay.

4. The method of claim 3, wherein the first relay includes a first control terminal for receiving a first control signal via the first control channel.

5. The method of claim 4, wherein the second switching element includes a second relay.

6. The method of claim 5, wherein the second relay includes a second control terminal for receiving a second control signal via the second control channel.

7. The method of claim 1, further comprising connecting a current clamp between the voltage supply and at least one of the first and second integrated circuits.

8. An apparatus for testing a plurality of integrated circuits, the plurality of integrated circuits including a first integrated circuit and a second integrated circuit, the apparatus comprising:
an integrated circuit test system that includes a voltage supply and a plurality of communication channels, the plurality of communication channels including a first communication channel designated as a first control channel and a second communication channel designated as a second control channel; and
an expansion system comprising:
a first switching element that is electrically connected between the voltage supply and the first integrated circuit; and
a second switching element that is electrically connected between the voltage supply and the second integrated circuit,
wherein the first and second switching elements are configured to be controlled by the first and second control channels, respectively.

9. The apparatus of claim 8, wherein the integrated circuit test system includes a Kalos 1 test system.

10. The apparatus of claim 8, wherein the first switching element includes a first relay.

11. The apparatus of claim 10, wherein the first relay includes a first control terminal for receiving a first control signal via the first control channel.

12. The apparatus of claim 11, wherein the second switching element includes a second relay.

13. The apparatus of claim 12, wherein the second relay includes a second control terminal for receiving a second control signal via the second control channel.

14. The apparatus of claim 8, further comprising a current clamp connected between the voltage supply and at least one of the first and second integrated circuits.
